(19) United States
(12) Patent Application Publication
(10) Pub. No.: US 2026/0123215 A1
(43) Pub. Date: Apr. 30, 2026

(54) DISPLAY DEVICE

(71) Applicant: LG Display Co., Ltd., Seoul (KR)

(72) Inventor: Taehwi KIM, Paju-si (KR)

(73) Assignee: LG Display Co., Ltd., Seoul (KR)

(21) Appl. No.: 19/335,683

(22) Filed: Sep. 22, 2025

(30) Foreign Application Priority Data
Oct. 29, 2024 (KR) 10-2024-0149973

(51) Int. Cl. H10K 59/131

(52) U.S. Cl. CPC H10K 59/131

(57) ABSTRACT

Embodiments of the present disclosure relate to a display device and, more specifically, to a display device capable of improving luminance uniformity in an optical area and enhancing light transmittance within the optical area by connecting a first signal line, which is electrically connected to a voltage line in a region adjacent to the optical area, to a second signal line.

### CROSS-REFERENCE TO RELATED APPLICATION

This application claims the benefit of and priority to Korean Patent Application No. 10-2024-0149973, filed on Oct. 29, 2024, the entire contents of which are incorporated herein by reference for all purposes as if fully set forth herein.

### BACKGROUND

### 1. Technical Field

The present disclosure relates to a display device.

### 2. Description of Related Art

With advancements in technology, display devices can provide not only image display functions but also various other functions such as image capturing and sensing. To achieve this, a display device requires optoelectronic devices (also referred to as light-receiving devices or sensors), such as cameras and sensing sensors.

Since an optoelectronic device needs to receive light from the front of the display device, it must be positioned in a location favorable for light reception. Accordingly, conventional display devices have had to render cameras (camera lenses) and sensing sensors exposed on the front of the display device. As a result, a bezel of the display panel becomes wider, or a notch or a physical hole is formed in a display area of the display panel to accommodate the optoelectronic device.

In other words, as optoelectronic devices such as cameras and sensing sensors, which receive front-facing light and perform designated functions, are included in a display device, the bezel of the display device may become larger, or design constraints may arise for the front design of the display device. Additionally, when a display device includes an optoelectronic device, unintended image quality degradation may occur due to the structure accommodating the optoelectronic device.

The description of related art should not be considered prior art merely because it is mentioned in or associated with this section. The description of related art includes information that describes one or more aspects of the subject technology, and the description in this section does not limit the scope of the invention.

### SUMMARY

Embodiments of the present disclosure may provide a display device in which an optoelectronic device is not exposed on the front of the display device, while still allowing the optoelectronic device disposed below a display panel of the display device to properly receive light through a light-transmitting structure.

Embodiments of the present disclosure may provide a display device that improves luminance uniformity in an optical area and enhances transmittance within the optical area by connecting a plurality of signal lines (for example, direct current signal lines, also referred to as DC signal lines) in a mesh structure in a region adjacent to the optical area.

Embodiments of the present disclosure may provide a display device that ensures luminance uniformity in the optical area, thereby improving optical characteristics and yield while enabling low-power operation.

Embodiments of the present disclosure may provide a display device comprising a display panel including an optical area and a general area. The optical area may comprise a plurality of transmissive areas and a plurality of first emission areas, and the general area may be disposed outside the optical area and may comprise a plurality of second emission areas. The display device may further include an optoelectronic device disposed below the display panel and overlapping the optical area. The general area may comprise a plurality of signal lines connected in a mesh structure in a region adjacent to the optical area.

The plurality of signal lines may include a plurality of first signal lines extending in a first direction and at least one second signal line extending in a second direction crossing the first direction. The second signal line may electrically connect at least two first signal lines, among the plurality of first signal lines, that are electrically connected to the same voltage line in a region adjacent to the optical area.

Embodiments of the present disclosure may provide a display device comprising a display panel including a general area and an optical area, where the optical area overlaps an optoelectronic device disposed below the display panel. The display panel may comprise: a substrate; a transistor layer disposed on the substrate and including at least one transistor and a passivation layer disposed on the at least one transistor; a first signal line disposed on the passivation layer in the general area and electrically connected to a voltage line; a plurality of planarization layers disposed on the transistor layer and the first signal line; a second signal line disposed on any one of the plurality of planarization layers in the general area and electrically connected to the first signal line in a region adjacent to the optical area; and a light-emitting device layer disposed on the plurality of planarization layers and including a plurality of light-emitting devices corresponding to each of the optical area and the general area.

According to embodiments of the present disclosure, a display device may be provided in which an optoelectronic device is not exposed on the front of the display device while still allowing the optoelectronic device disposed below the display panel of the display device to properly receive light through a light-transmitting structure.

According to embodiments of the present disclosure, by connecting signal lines (for example, direct current signal lines, hereinafter is referred to as DC signal lines) in a mesh structure in a region adjacent to the optical area, luminance variation in the optical area may be improved, and transmittance within the optical area may be enhanced.

According to embodiments of the present disclosure, luminance uniformity in the optical area may be ensured, thereby improving optical characteristics and yield while enabling low-power operation.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further aspects and advantages are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure.

FIG. 1A to FIG. 1E are diagrams illustrating a display device according to embodiments of the present disclosure.

FIG. 2 is a diagram illustrating a system configuration of a display device according to embodiments of the present disclosure.

FIG. 3 is a diagram illustrating an example of a sub-pixel according to embodiments of the present disclosure.

FIG. 4 is a diagram illustrating another example of a sub-pixel according to embodiments of the present disclosure.

FIG. 5 is a diagram illustrating the arrangement of sub-pixels in a general area and an optical area according to embodiments of the present disclosure.

FIG. 6 is a diagram illustrating an example of a signal line connection structure in a display panel according to embodiments of the present disclosure.

FIG. 7 is a diagram illustrating another example of a signal line connection structure in a display panel according to embodiments of the present disclosure.

FIG. 8 and FIG. 9 are diagrams further illustrating the signal line connection structure in a display panel according to embodiments of the present disclosure.

FIG. 10 and FIG. 11 are diagrams illustrating implementation examples of a display device according to embodiments of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

In the following description of examples or embodiments of the present invention, reference will be made to the accompanying drawings in which it is shown by way of illustration specific examples or embodiments that can be implemented, and in which the same reference numerals and signs can be used to designate the same or like components even when they are shown in accompanying drawings different from one another. Further, in the following description of examples or embodiments of the present invention, detailed descriptions of well-known functions and components incorporated herein will be omitted when it is determined that the description may make the subject matter in some embodiments of the present invention rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

Terms, such as “first”, “second”, “A”, “B”, “(A)”, or “(B)” may be used herein to describe elements of the present invention. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to” “contact or overlap”, etc. each other.

When time relative terms, such as “after”, “subsequent to”, “next”, “before”, and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the present disclosure will be described in detail with reference to the accompanying drawings.

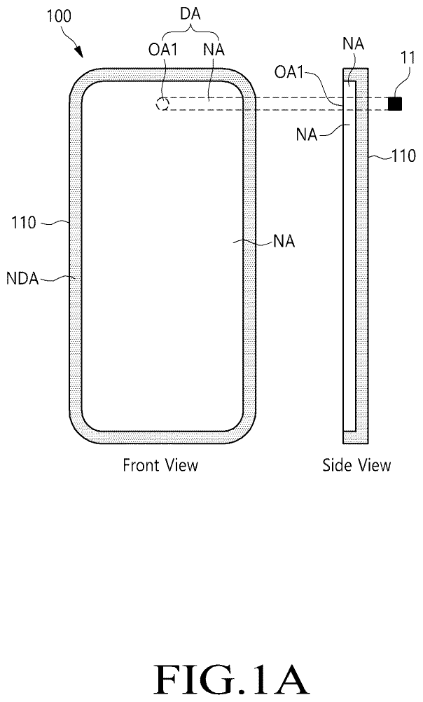

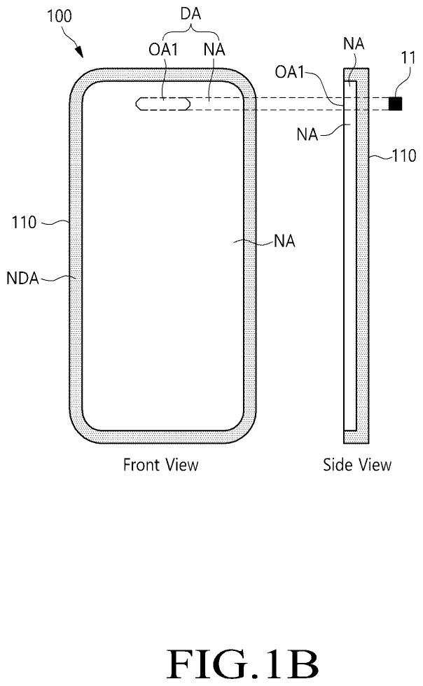

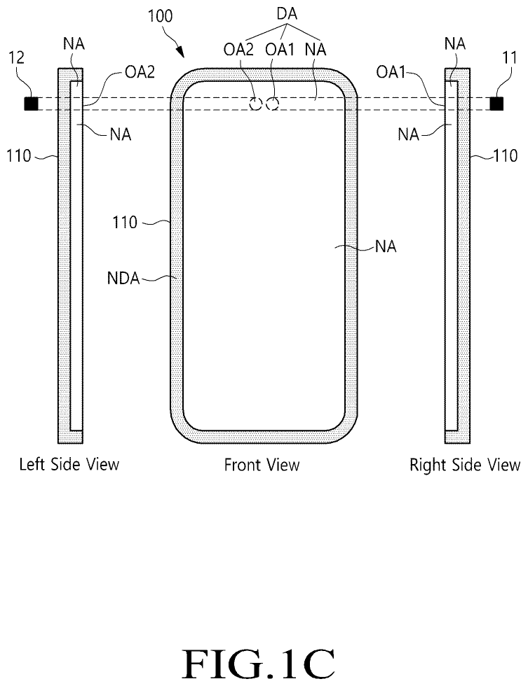

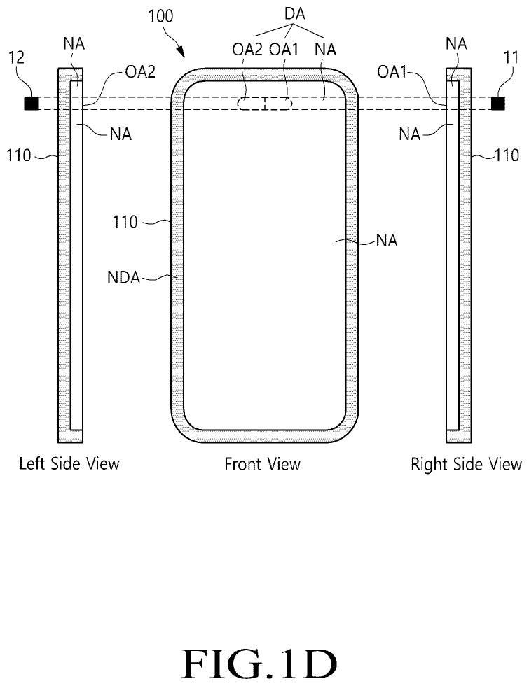

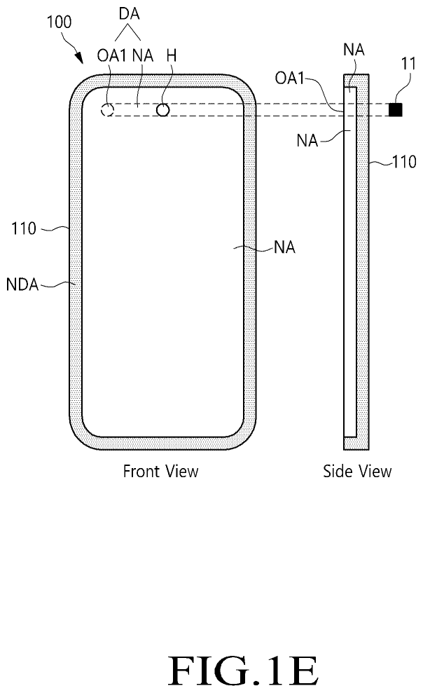

FIG. 1A to FIG. 1E are diagrams illustrating a display device 100 according to embodiments of the present disclosure.

Referring to FIG. 1A to FIG. 1E, the display device 100 according to embodiments of the present disclosure may include a display panel 110 that displays images and at least one optoelectronic device (for example, a first optoelectronic device 11 and a second optoelectronic device 12).

The display panel 110 may include a display area DA, where images are displayed, and a non-display area NDA, where images are not displayed.

In the display area DA, a plurality of sub-pixels may be arranged, and various signal lines for driving the plurality of sub-pixels may be provided.

The non-display area NDA may be an outer region of the display area DA. Various signal lines may be arranged in the non-display area NDA, and various driving circuits may be connected thereto. The non-display area NDA may be bent so that it is not visible from the front (or a front surface) or may be covered by a case (not shown). The non-display area NDA is also referred to as a bezel or a bezel area.

Referring to FIG. 1A to FIG. 1D, in the display device 100 according to embodiments of the present disclosure, the at least one optoelectronic device (for example, the first optoelectronic device 11 and the second optoelectronic device 12) may be an electronic component positioned below the display panel 110 (i.e., on the opposite side of a viewing surface).

External light may enter through the front surface (viewing surface) of the display panel 110, pass through the display panel 110, and be transmitted to the at least one optoelectronic device (for example, the first optoelectronic device 11 and the second optoelectronic device 12) positioned below the display panel 110.

The at least one optoelectronic device (for example, the first optoelectronic device 11 and the second optoelectronic device 12) may receive external light transmitted through the display panel 110 and perform a predetermined function based on the received external light. For example, the at least one optoelectronic device (for example, the first optoelectronic device 11 and the second optoelectronic device 12) may include at least one of an imaging device such as a camera (image sensor) and a sensing sensor such as a proximity sensor or an ambient light sensor.

Referring to FIG. 1A to FIG. 1E, in the display panel 110 according to embodiments of the present disclosure, the display area DA may include a general area NA and at least one optical area (for example, a first optical area OA1 and a second optical area OA2).

The at least one optical area (for example, the first optical area OA1 and the second optical area OA2) may be an area overlapping at least one optoelectronic device (for example, the first optoelectronic device 11 and the second optoelectronic device 12).

According to the example in FIG. 1A, the display area DA may include the general area NA and the first optical area OA1. Here, at least a portion of the first optical area OA1 may overlap the first optoelectronic device 11.

In FIG. 1A, the first optical area OA1 is illustrated as having a circular shape; however, the shape of the first optical area OA1 according to embodiments of the present disclosure is not limited thereto.

For example, as illustrated in FIG. 1B, the first optical area OA1 may have an octagonal shape, and it may also have various polygonal shapes.

According to the example in FIG. 1C, the display area DA may include the general area NA, the first optical area OA1, and the second optical area OA2. In the example of FIG. 1C, the general area NA may be arranged between the first optical area OA1 and the second optical area OA2 (that is, the first optical area OA1 and the second optical area OA2 may be not in contact with each other). Here, at least a portion of the first optical area OA1 may overlap the first optoelectronic device 11, and at least a portion of the second optical area OA2 may overlap the second optoelectronic device 12.

According to the example in FIG. 1D, the display area DA may include the general area NA, the first optical area OA1, and the second optical area OA2. In the example of FIG. 1D, the general area NA may not be disposed between the first optical area OA1 and the second optical area OA2. That is, the first optical area OA1 and the second optical area OA2 may be in contact with each other. Here, at least a portion of the first optical area OA1 may overlap the first optoelectronic device 11, and at least a portion of the second optical area OA2 may overlap the second optoelectronic device 12.

According to the example in FIG. 1E, the display panel 110 further includes a hole area H, in which the second optoelectronic device 12 is disposed and which is surrounded by the general area NA. In the hole area H, the second optoelectronic device 12 may be positioned above the display panel 110. However, embodiments of the present disclosure are not limited thereto, and the hole area H may be a second optical area OA2 in which the second optoelectronic device 12 is positioned below the display panel 110 within the display area DA.

The display area DA on the display panel 110 may include the first optical area OA1 and the general area NA.

According to the example in FIG. 1E, a general area NA is disposed between the first optical area OA1 and the hole area H, and the hole area H is disposed on an imaginary centerline that vertically divides the display panel 110. The first optical area OA1 may be spaced apart from the hole area H to the left or right with respect to the imaginary centerline.

In FIG. 1E, the first optical area OA1 and the hole area H are illustrated as having the same size; however, embodiments of the present disclosure are not limited thereto. For example, the sizes of the first optical area OA1 and the hole area H may be different. For instance, the size of the first optical area OA1 may be smaller than the size of the hole area H.

The display device 100 according to embodiments of the present disclosure may improve the transmittance of at least one optical area (for example, the first optical area OA1 and the second optical area OA2) by removing signal lines (for example, DC signal lines) in the at least one optical area (for example, the first optical area OA1 and the second optical area OA2). In this case, if the at least one optical area (for example, the first optical area OA1 and the second optical area OA2) is positioned on one side of the display panel 110, i.e., on the left or right side with respect to the imaginary centerline as illustrated in the example of FIG. 1E, an RC load difference may occur in a common power line, such as DC signal lines, disposed in the left and right non-display areas NDA of the display panel 110. Accordingly, a left/right luminance variation may occur within the at least one optical area (for example, the first first optical area OA1 and the second optical area OA2).

Accordingly, the display device 100 according to embodiments of the present disclosure may improve the left/right luminance deviation within the at least one optical area (for example, the first optical area OA1 and the second optical area OA2) due to differences in an RC load by connecting at least one signal line (for example, DC signal line) in a mesh structure using a data dummy line. Additionally, it may enhance the transmittance of the at least one optical area (for example, the first optical area OA1 and the second optical area OA2).

For example, the DC signal line may include at least one of an initialization voltage line providing an initialization voltage Vini, a reset voltage line providing a reset voltage VAR, and a bias voltage line applying a bias voltage VOBS.

The at least one optical area (for example, the first optical area OA1 and the second optical area OA2) may include both an image display structure and a light-transmitting structure. That is, since the at least one optical area (for example, the first optical area OA1 and the second optical area OA2) is part of the display area DA, sub-pixels for image display must be arranged in the at least one optical area (for example, the first optical area OA1 and the second optical area OA2). Furthermore, the at least one optical area (for example, the first optical area OA1 and the second optical area OA2) must include a light-transmitting structure to allow light to pass through to the at least one optoelectronic device (for example, the first optoelectronic device 11 and the second optoelectronic device 12).

Hereinafter, the image display structure may be referred to as an emission area, and the light-transmitting structure may be referred to as a transmissive area.

The at least one optoelectronic device (for example, the first optoelectronic device 11 and the second optoelectronic device 12) is a device that requires light reception; however, it is positioned below the display panel 110 (on the opposite side of the viewing surface) and can receive light transmitted through the display panel 110.

The at least one optoelectronic device (for example, the first optoelectronic device 11 and the second optoelectronic device 12) is not exposed on the front surface (viewing surface) of the display panel 110. Accordingly, when a user looks at the front of the display device 100, the optoelectronic devices 11 and 12 may not be visible.

For example, the first optoelectronic device 11 may be a sensing sensor such as a proximity sensor or an ambient light sensor, while the second optoelectronic device 12 may be a camera. The sensing sensor, for example, may be an infrared sensor that detects infrared rays.

Conversely, the first optoelectronic device 11 may be a camera, and the second optoelectronic device 12 may be a sensing sensor.

Hereinafter, for convenience of explanation, an example will be described in which the first optoelectronic device 11 is a sensing sensor, and the second optoelectronic device 12 is a camera. Here, the camera may refer to a camera lens or an image sensor.

When the second optoelectronic device 12 is a camera, the camera is positioned below the display panel 110 but may be a front camera that captures images in the front direction of the display panel 110. Accordingly, a user may take pictures using the camera, which is not visible on the viewing surface while looking at the viewing surface of the display panel 110.

The general area NA and the at least one optical area (for example, the first optical area OA1 and the second optical area OA2) are display areas DA capable of displaying images. However, the general area NA is an area where a light-transmitting structure does not need to be formed, whereas the at least one optical area (for example, the first optical area OA1 and the second optical area OA2) is an area where a light-transmitting structure must be formed.

Accordingly, the at least one optical area (for example, the first optical area OA1 and the second optical area OA2) is required to have a transmittance above a certain level, whereas the general area NA may have no light transmittance or may have a low transmittance below a certain level.

For example, the at least one optical area (for example, the first optical area OA1 and the second optical area OA2) and the general area NA may differ in terms of resolution, sub-pixel arrangement structure, the number of sub-pixels per unit area, electrode structure, line (or wiring) structure, electrode arrangement structure, or line (or wiring) arrangement structure.

For example, the number of sub-pixels per unit area in the at least one optical area (for example, the first optical area OA1 and the second optical area OA2) may be smaller than that in the general area NA. That is, the resolution of the at least one optical area (for example, the first optical area OA1 and the second optical area OA2) may be lower than that of the general area NA. Here, the number of sub-pixels per unit area is a unit for measuring resolution and may also be referred to as PPI (Pixels Per Inch), which indicates the number of pixels per inch.

For example, the number of sub-pixels per unit area in the first optical area OA1 may be smaller than that in the general area NA. The number of sub-pixels per unit area in the second optical area OA2 may be equal to or greater than that in the first optical area OA1.

Each of the first optical area OA1 and the second optical area OA2 may have various shapes such as a circle, an ellipse, a rectangle, a hexagon, or an octagon. The first optical area OA1 and the second optical area OA2 may have the same shape or different shapes.

Referring to FIG. 1D, when the first optical area OA1 and the second optical area OA2 are in contact with each other, the entire optical area, including the first optical area OA1 and the second optical area OA2, may also have various shapes such as a circle, an ellipse, a rectangle, a hexagon, or an octagon.

Hereinafter, for convenience of explanation, an example will be described in which each of the first optical area OA1 and the second optical area OA2 is circular.

Since the display device 100 according to embodiments of the present disclosure does not require a notch or hole in the display panel 110 for exposing a camera or a sensing sensor, the area of the display area DA may not be reduced.

Accordingly, since the display panel 110 does not require a notch or camera hole for exposing a camera or a sensing sensor, the size of the bezel area may be reduced, and design constraints may be eliminated, thereby increasing the degree of freedom in design.

Even though the at least one optoelectronic device (for example, the first optoelectronic device 11 and the second optoelectronic device 12) is positioned behind (or below) the display panel 110 in the display device 100 according to embodiments of the present disclosure, the at least one optoelectronic device (for example, the first optoelectronic device 11 and the second optoelectronic device 12) must be able to properly receive light and perform its designated functions normally.

Additionally, in the display device 100 according to embodiments of the present disclosure, even though at least one optoelectronic device (for example, the first optoelectronic device 11 and the second optoelectronic device 12) is hidden behind the display panel 110 and overlaps the display area DA, normal image display must be possible in at least one optical area OA1 and OA2 overlapping the at least one optoelectronic device (for example the first optoelectronic device 11 and the second optoelectronic device 12) within the display area DA.

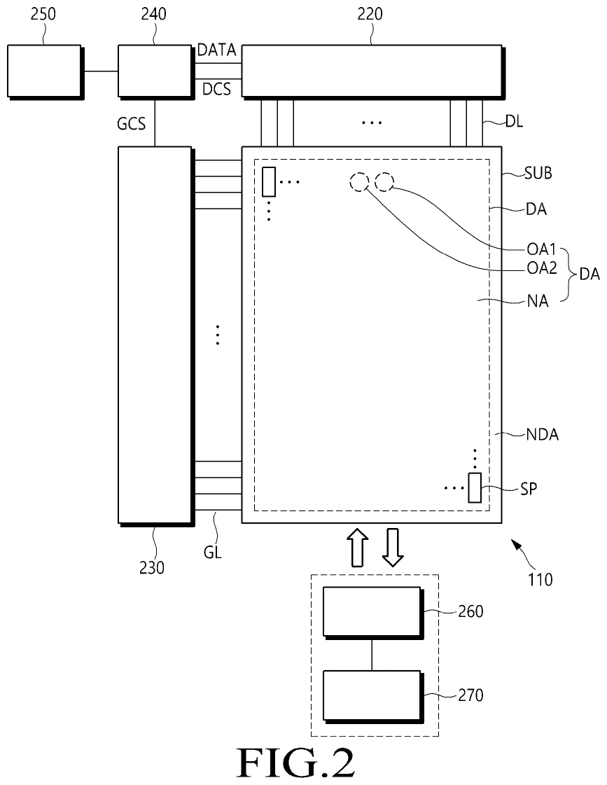

FIG. 2 is a diagram illustrating the system configuration of the display device 100 according to embodiments of the present disclosure.

Referring to FIG. 2, the display device 100 may include a display panel 110 and a display driving circuit as components for image display.

The display driving circuit is a circuit for driving the display panel 110 and may include a data driving circuit 220, a gate driving circuit 230, and a controller 240.

The display panel 110 may include a display area DA where images are displayed and a non-display area NDA where images are not displayed. The non-display area NDA may be an outer region of the display area DA and may also be referred to as a bezel area. The entire or part of the non-display area NDA may be visible from the front of the display device 100 or may be bent so that it is not visible from the front of the display device 100.

The display panel 110 may include a substrate SUB and a plurality of sub-pixels SP disposed on the substrate SUB. Additionally, the display panel 110 may further include various types of signal lines for driving the plurality of sub-pixels SP.

The display device 100 according to embodiments of the present disclosure may be a liquid crystal display (or liquid crystal display device) or a self-emissive display (or self-emissive display device) in which the display panel 110 emits light on its own. If the display device 100 is a self-emissive display, each of the plurality of sub-pixels SP may include a light-emitting device.

For example, the display device 100 according to embodiments of the present disclosure may be an organic light-emitting display device in which the light-emitting device is implemented as an organic light-emitting diode (OLED). In another example, the display device 100 may be an inorganic light-emitting display device in which the light-emitting device is implemented as an inorganic-based light-emitting diode. In yet another example, the display device 100 may be a quantum dot display device in which the light-emitting device is implemented as a quantum dot, which is a semiconductor crystal that emits light on its own.

The structure of each of the plurality of sub-pixels SP may vary depending on the type of display device 100. For example, if the display device 100 is a self-emissive display in which the sub-pixels SP emit light on their own, each sub-pixel SP may include a light-emitting device, which self-emits light, at least one transistor, and at least one capacitor.

For example, various types of signal lines may include a plurality of data lines DL that transmit data signals (also referred to as data voltages or image signals) and a plurality of gate lines GL that transmit gate signals (also referred to as scan signals and/or emission control signals).

The plurality of data lines DL and the plurality of gate lines GL may intersect with each other. Each of the plurality of gate lines GL may be disposed to extend in a first direction, and each of the plurality of data lines DL may be disposed to extend in a second direction.

Here, the first direction may be a horizontal (row) direction, and the second direction may be a vertical (column) direction. Alternatively, the first direction may be the vertical direction, and the second direction may be the horizontal direction.

The data driving circuit 220 is a circuit for driving the plurality of data lines DL and may output data signals to the plurality of data lines DL. The gate driving circuit 230 is a circuit for driving the plurality of gate lines GL and may output gate signals to the plurality of gate lines GL.

The controller 240 is a device for controlling the data driving circuit 220 and the gate driving circuit 230 and may control the driving timing of the plurality of data lines DL and the plurality of gate lines GL.

The controller 240 may supply a data driving control signal DCS to the data driving circuit 220 to control the data driving circuit 220 and may supply a gate driving control signal GCS to the gate driving circuit 230 to control the gate driving circuit 230.

The controller 240 may receive input image data from a host system 250 and supply image data DATA to the data driving circuit 220 based on the input image data.

The data driving circuit 220 may supply data signals to the plurality of data lines DL according to the driving timing control of the controller 240.

The data driving circuit 220 may receive digital image data DATA from the controller 240, convert the received image data DATA into analog data signals, and output the analog data signals to the plurality of data lines DL.

The gate driving circuit 230 may supply gate signals to the plurality of gate lines GL according to the timing control of the controller 240. The gate driving circuit 230 may receive a first gate voltage corresponding to a turn-on level voltage and a second gate voltage corresponding to a turn-off level voltage along with various gate driving control signals GCS, generate gate signals, and supply the generated gate signals to the plurality of gate lines GL.

For example, the data driving circuit 220 may be connected to the display panel 110 using a Tape Automated Bonding (TAB) method, or it may be connected to a bonding pad of the display panel 110 using a Chip On Glass (COG) method or a Chip On Panel (COP) method. Additionally, it may be implemented using a Chip On Film (COF) method and connected to the display panel 110.

The gate driving circuit 230 may be connected to the display panel 110 using a Tape Automated Bonding (TAB) method, or it may be connected to a bonding pad of the display panel 110 using a Chip On Glass (COG) method or a Chip On Panel (COP) method. Alternatively, it may be connected to the display panel 110 using a Chip On Film (COF) method. Additionally, the gate driving circuit 230 may be formed in the non-display area NDA of the display panel 110 as a Gate In Panel (GIP) type. The gate driving circuit 230 may be disposed on or connected to the substrate. Specifically, when the gate driving circuit 230 is of the GIP type, it may be disposed in the non-display area NDA of the display panel 110 (or the substrate). When the gate driving circuit 230 is of the Chip On Glass (COG) type or the Chip On Film (COF) type, it may be connected to the substrate.

Meanwhile, at least one of the data driving circuit 220 and the gate driving circuit 230 may be disposed in the display area DA of the display panel 110. For example, at least one of the data driving circuit 220 and the gate driving circuit 230 may be disposed such that it does not overlap with the sub-pixels SP or may be disposed to partially or entirely overlap the sub-pixels SP.

The data driving circuit 220 may be connected to one side (e.g., the upper or lower side) of the display panel 110. Depending on the driving method or panel design method, the data driving circuit 220 may be connected to both sides (e.g., the upper and lower sides) of the display panel 110 or to two or more sides among the four sides of the display panel 110.

The gate driving circuit 230 may be connected to one side (e.g., the left or right side) of the display panel 110. Depending on the driving method or panel design method, the gate driving circuit 230 may be connected to both sides (e.g., the left and right sides) of the display panel 110 or to two or more sides among the four sides of the display panel 110.

The controller 240 may be implemented as a component separate from the data driving circuit 220 or may be integrated with the data driving circuit 220 and implemented as an integrated circuit.

The controller 240 may be a timing controller commonly used in display technologies, a control device that includes a timing controller and performs additional control functions, or a control device separate from the timing controller. Alternatively, it may be a circuit within a control device. The controller 240 may be implemented using various circuits or electronic components, such as an Integrated Circuit (IC), a Field Programmable Gate Array (FPGA), an Application Specific Integrated Circuit (ASIC), or a processor.

The controller 240 may be mounted on a printed circuit board or a flexible printed circuit and electrically connected to the data driving circuit 220 and the gate driving circuit 230 through the printed circuit board or the flexible printed circuit.

The controller 240 may transmit and receive signals to and from the data driving circuit 220 according to at least one predefined interface. For example, the interface may include Low Voltage Differential Signaling (LVDS), Embedded Clock Point-to-Point Interface (EPI), or Serial Peripheral Interface (SPI).

The display device 100 according to embodiments of the present disclosure may further include a touch sensor and a touch sensing circuit that senses the touch sensor to detect whether a touch has occurred by a touch object, such as a finger or a pen, or to detect the touch position, in order to provide not only an image display function but also a touch sensing function.

The touch sensing circuit may include a touch driving circuit 260, which drives and senses the touch sensor to generate and output touch sensing data, and a touch controller 270, which detects touch occurrence or determines the touch position based on the touch sensing data.

The touch sensor may include a plurality of touch electrodes. Additionally, the touch sensor may further include a plurality of touch lines to electrically connect the plurality of touch electrodes to the touch driving circuit 260.

The touch sensor may exist externally in the form of a touch panel or may be located inside the display panel 110. When the touch sensor is externally present as a touch panel, it is referred to as an external type. If the touch sensor is of the external type, the touch panel and the display panel 110 are separately manufactured and may be combined during a assembly process. The external-type touch panel may include a touch panel substrate and a plurality of touch electrodes on the touch panel substrate.

When the touch sensor is located inside the display panel 110, the touch sensor may be formed on the substrate SUB during the manufacturing process of the display panel 110, along with signal lines and electrodes related to display driving.

The touch driving circuit 260 may supply a touch driving signal to at least one of the plurality of touch electrodes and sense at least one of the plurality of touch electrodes to generate touch sensing data.

The touch sensing circuit may perform touch sensing using a self-capacitance sensing method or a mutual-capacitance sensing method.

When the touch sensing circuit performs touch sensing using the self-capacitance sensing method, it may detect touch based on the capacitance between each touch electrode and a touch object (e.g., a finger or a pen).

In the self-capacitance sensing method, each of the plurality of touch electrodes may serve as both a driving touch electrode and a sensing touch electrode. The touch driving circuit 260 may drive and sense all or a portion of the plurality of touch electrodes.

When the touch sensing circuit performs touch sensing using the mutual-capacitance sensing method, it may detect touch based on the capacitance between touch electrodes.

In the mutual-capacitance sensing method, the plurality of touch electrodes may be divided into driving touch electrodes and sensing touch electrodes. The touch driving circuit 260 may drive the driving touch electrodes and sense the sensing touch electrodes.

The touch driving circuit 260 and the touch controller 270 included in the touch sensing circuit may be implemented as separate devices or as a single integrated device. Additionally, the touch driving circuit 260 and the data driving circuit 220 may also be implemented as separate devices or as a single integrated device.

The display device 100 may further include a power supply circuit that supplies various power sources to the display driving circuit and/or the touch sensing circuit.

The display device 100 according to embodiments of the present disclosure may be a mobile terminal such as a smartphone or tablet, or a monitor or television (TV) of various sizes. However, the display device 100 is not limited thereto and may encompass various types and sizes of displays capable of presenting information or images.

As described above, the display area DA in the display panel 110 may include a general area NA and at least one optical area (for example, the first optical area OA1 and the second optical area OA2).

The general area NA and the at least one optical area (for example, the first optical area OA1 and the second optical area OA2) are regions capable of displaying images. However, in an aspect, the general area NA does not require a light-transmitting structure, whereas the at least one optical area (for example, the first optical area OA1 and the second optical area OA2) must have a light-transmitting structure.

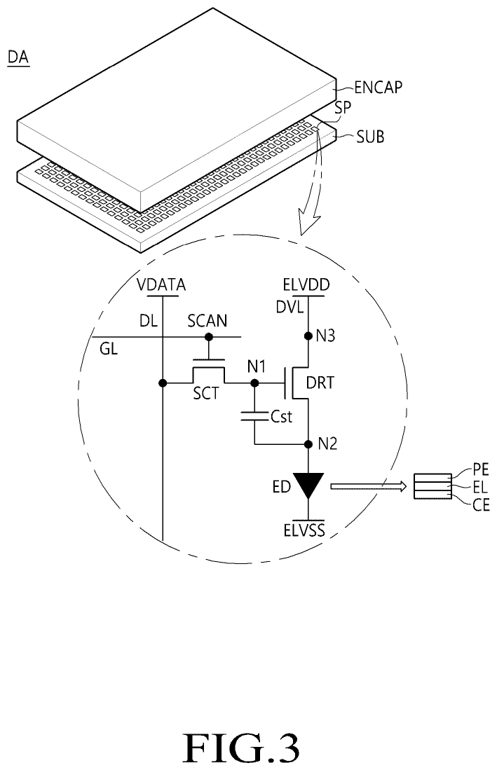

FIG. 3 is a diagram illustrating an example of a sub-pixel SP according to embodiments of the present disclosure.

Referring to FIG. 3, each of a plurality of sub-pixels SP disposed in the general area NA, the first optical area OA1, and the second optical area OA2, which are included in the display area DA of the display panel 110, may be disposed on a substrate SUB. Each sub-pixel SP may include a light-emitting device ED disposed in an emission area, a driving transistor DRT for driving the light-emitting device ED, a scan transistor SCT for transmitting a data voltage VDATA to a first node N1 of the driving transistor DRT, and a storage capacitor Cst for maintaining a certain voltage for one frame period.

The driving transistor DRT may include a first node N1 to which the data voltage is applied, a second node N2 electrically connected to the light-emitting device ED, and a third node N3 to which a driving voltage ELVDD is applied from a driving voltage line DVL.

The first node N1 of the driving transistor DRT may be a gate node of the driving transistor DRT and may be electrically connected to a source node or a drain node of the scan transistor SCT.

The second node N2 of the driving transistor DRT may be a source node or a drain node of the driving transistor DRT and may be electrically connected to a pixel electrode PE of the light-emitting device ED.

The third node N3 of the driving transistor DRT may be a drain node or a source node of the driving transistor DRT.

The storage capacitor Cst may be connected between the first node N1 and the second node N2 of the driving transistor DRT. The storage capacitor Cst is charged with an amount of charge corresponding to the voltage difference between two ends thereof and functions to maintain the voltage difference for a predetermined frame period. Accordingly, the corresponding sub-pixel SP may emit light during the predetermined frame period.

The scan transistor SCT may be controlled by a gate signal and may be connected between the first node N1 of the driving transistor DRT and the data line DL.

The scan transistor SCT may be turned on by a gate signal of a turn-on level voltage supplied from the gate line GL, thereby transmitting the data voltage VDATA supplied from the data line DL to the first node N1 of the driving transistor DRT.

The scan transistor SCT and the driving transistor DRT may be n-type transistors or p-type transistors.

If the scan transistor SCT is an n-type transistor, the turn-on level voltage of the gate signal may be a high-level voltage. If the scan transistor SCT is a p-type transistor, the turn-on level voltage of the gate signal may be a low-level voltage.

The light-emitting device ED may include a pixel electrode PE, a light-emitting layer EL, and a common electrode CE. A reference voltage ELVSS may be applied to the common electrode CE.

For example, the pixel electrode PE may be an anode electrode, and the common electrode CE may be a cathode electrode. Conversely, the pixel electrode PE may be a cathode electrode, and the common electrode CE may be an anode electrode. Hereinafter, for convenience of explanation, it is assumed that the pixel electrode PE is an anode electrode and the common electrode CE is a cathode electrode.

For example, the light-emitting device ED may be an organic light-emitting diode (OLED), an inorganic light-emitting diode, or a quantum dot light-emitting device. In this case, if the light-emitting device ED is an OLED, the light-emitting layer EL in the light-emitting device ED may include an organic light-emitting layer containing organic materials.

The storage capacitor Cst is not an internal capacitor (e.g., parasitic capacitors such as Cgs or Cgd) that exists between the gate node and the source node (or drain node) of the driving transistor DRT. Instead, the storage capacitor Cst may be an external capacitor that is intentionally designed outside the driving transistor DRT.

Since the circuit elements (especially, the light-emitting device ED) in each sub-pixel SP are vulnerable to external moisture and oxygen, an encapsulation layer ENCAP may be disposed in the display panel to prevent the penetration of moisture or oxygen into the circuit elements (especially, the light-emitting device ED). The encapsulation layer ENCAP may be disposed to cover the light-emitting devices ED.

The structure of the sub-pixel SP shown in FIG. 3 is merely an example and may be variously modified to include one or more additional transistors or one or more additional capacitors.

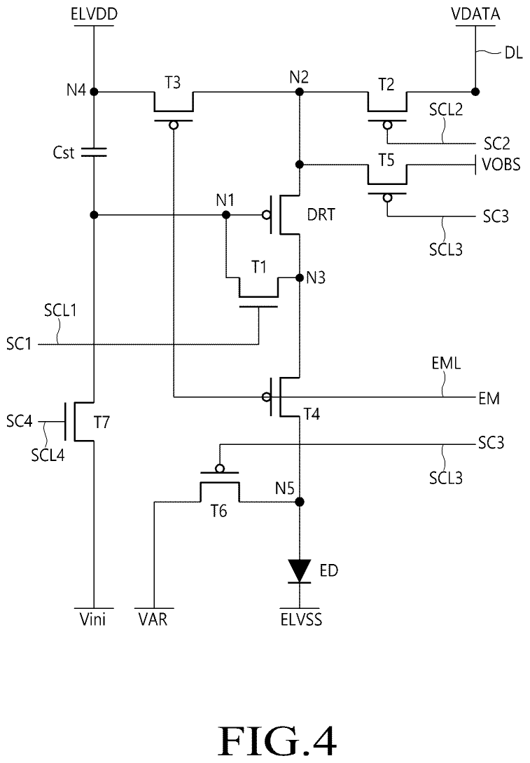

For example, the sub-pixel SP may further include a plurality of transistors electrically connected to each of a DC signal line, such as an initialization voltage line, a reset voltage line, and a bias voltage line. The structure of a sub-pixel SP electrically connected to a DC signal line will be described below with reference to the embodiment shown in FIG. 4.

FIG. 4 is a diagram illustrating another example of a sub-pixel SP according to embodiments of the present disclosure.

Referring to FIG. 4, each of the plurality of sub-pixels SP may be connected to a data line DL supplying a data voltage VDATA, a first scan line SCL1 supplying a first scan signal SC1, a second scan line SCL2 supplying a second scan signal SC2, a third scan line SCL3 supplying a third scan signal SC3, a fourth scan line SCL4 supplying a fourth scan signal SC4, and an emission control signal line EML supplying an emission control signal EM.

The gate driving circuit 230 may output each of the first to fourth scan signals SC1 to SC4 and the emission control signal EM to the first to fourth scan lines SCL1 to SCL4 and the emission control signal line EML. To achieve this, the gate driving circuit 230 may include first to fourth scan drivers that generate the first to fourth scan signals SC1 to SC4, respectively, and an emission control driver that generates the emission control signal EM. However, embodiments of the present disclosure are not limited thereto.

Referring to FIG. 4, the sub-pixel SP may include a driving transistor DRT, first to seventh transistors T1 to T7, a storage capacitor Cst, and a light-emitting device ED.

Each of the transistors (for example, the driving transistor DRT and the first to seventh transistors T1 to T7) may include a first electrode, a second electrode, and a gate electrode. One of the first electrode and the second electrode may be a source electrode, and the other may be a drain electrode.

Each of the transistors (for example, the driving transistor DRT and the first to seventh transistors T1 to T7) may be either a p-type or an n-type transistor. In the example of FIG. 4, the first transistor T1 and the seventh transistor T7 are n-type transistors, while the remaining transistors (for example, the driving transistor DRT and the second to sixth transistors T2 to T6) are p-type transistors. However, embodiments of the present disclosure are not limited thereto, and all or some of the transistors (for example, the driving transistor DRT and the first to seventh transistors T1 to T7) may be either p-type or n-type transistors. Additionally, the n-type transistors may be oxide thin-film transistors (TFTs) or polycrystalline silicon TFTs, while the p-type transistors may be polycrystalline silicon TFTs or oxide TFTs.

Hereinafter, the description will be provided under the assumption that the first transistor T1 and the seventh transistor T7 are n-type transistors, while the remaining transistors (for example, the driving transistor DRT and the second to sixth transistors T2 to T6) are p-type transistors. Accordingly, the first transistor T1 and the seventh transistor T7 may be turned on when a high-level voltage is applied to their gate nodes, whereas the remaining transistors (for example, the driving transistor DRT and the second to sixth transistors T2 to T6) may be turned on when a low-level voltage is applied to their gate nodes.

The first transistor T1 may function as a compensation transistor, the second transistor T2 may function as a data supply transistor, the third and fourth transistors T3 and T4 may function as emission control transistors, the fifth transistor T5 may function as a bias transistor, and the sixth and seventh transistors T6 and T7 may function as initialization transistors.

The light-emitting device ED may include a pixel electrode (e.g., an anode electrode) and a common electrode (e.g., a cathode electrode). The pixel electrode of the light-emitting device ED may be connected to the fifth node N5, and a reference voltage ELVSS may be applied to the common electrode.

The driving transistor DRT may include a first electrode connected to the second node N2, a second electrode connected to the third node N3, and a gate electrode connected to the first node N1. The driving transistor DRT may supply a driving current to the light-emitting device ED based on the voltage at the first node N1 (or the data voltage stored in the storage capacitor Cst).

The first transistor T1 may include a first electrode connected to the first node N1, a second electrode connected to the third node N3, and a gate electrode receiving the first scan signal SC1. The first transistor T1 may be turned on in response to the first scan signal SC1. When the first transistor T1 is turned on, the first node N1 and the third node N3 are electrically connected, causing the driving transistor DRT to be in a diode-connected state, thereby allowing its threshold voltage Vth to be sampled. In this sense, the first transistor T1 may be referred to as a compensation transistor.

The storage capacitor Cst may be connected or formed between the first node N1 and the fourth node N4. The storage capacitor Cst may store or maintain the driving voltage ELVDD.

The second transistor T2 may include a first electrode receiving a data voltage VDATA through a data line DL, a second electrode connected to the second node N2, and a gate electrode receiving the second scan signal SC2.

The second transistor T2 may be turned on in response to the second scan signal SC2, thereby transferring the data voltage VDATA to the second node N2. In this sense, the second transistor T2 may be referred to as a data supply transistor.

The third transistor T3 may be connected between the fourth node N4 and the second node N2, while the fourth transistor T4 may be connected between the third node N3 and the fifth node N5. These transistors may form a current flow path through which the driving current flows. Here, the third and fourth transistors T3 and T4 may also be referred to as the first and second emission control transistors, respectively.

The third transistor T3 may include a first electrode connected to the fourth node N4, to which a driving voltage EVDD is applied, a second electrode connected to the second node N2, and a gate electrode receiving the emission control signal EM.

The fourth transistor T4 may include a first electrode connected to the third node N3, a second electrode connected to the fifth node N5, and a gate electrode receiving the emission control signal EM. Here, the fifth node N5 may electrically correspond to the anode electrode of the light-emitting device ED.

The third and fourth transistors T3 and T4 may be turned on simultaneously in response to the emission control signal EM(n). When the third and fourth transistors T3 and T4 are turned on, a driving current may be supplied to the light-emitting device ED. The light-emitting device ED may emit light with a luminance corresponding to the driving current.

The fifth transistor T5 may include a first electrode to which a bias voltage VOBS is applied through a bias voltage line, a second electrode connected to the second node N2, and a gate electrode to which the third scan signal SC3 is applied. The fifth transistor T5 may also be referred to as a bias transistor.

The sixth transistor T6 may include a first electrode to which a reset voltage VAR is applied through a reset voltage line, a second electrode connected to the fifth node N5, and a gate electrode to which the third scan signal SC3 is applied.

The sixth transistor T6 may be turned on in response to the third scan signal SC3 before (or after) the light-emitting device ED emits light. Accordingly, the reset voltage VAR may be applied to the fifth node N5, thereby initializing the anode electrode (or pixel electrode) of the light-emitting device ED.

The light-emitting device ED may have a parasitic capacitor formed between its anode and cathode electrodes. While the light-emitting device ED emits light, the parasitic capacitor may be charged, causing the anode electrode of the light-emitting device ED to have a specific voltage. Accordingly, by applying the reset voltage VAR to the anode electrode of the light-emitting device ED through the sixth transistor T6, the charge accumulated in the light-emitting device ED may be reset.

According to the example of FIG. 4, the gate electrodes of the fifth and sixth transistors T5 and T6 may be configured to commonly receive the third scan signal SC3. However, embodiments of the present disclosure are not limited thereto, and the fifth and sixth transistors T5 and T6 may be configured to receive different scan signals so that they can be controlled independently.

The seventh transistor T7 may include a first electrode to which an initialization voltage Vini is applied through an initialization voltage line, a second electrode connected to the first node N1, and a gate electrode to which the fourth scan signal SC4 is applied.

The seventh transistor T7 may be turned on in response to the fourth scan signal SC4. Accordingly, the initialization voltage Vini may be applied to the first node N1, which corresponds to the gate electrode of the driving transistor DRT. Accordingly, the gate electrode of the driving transistor DRT may be initialized.

Unnecessary charge may remain in the gate electrode of the driving transistor DRT due to the driving voltage EVDD stored in the capacitor Cst. Thus, by applying the initialization voltage Vini to the gate electrode of the driving transistor DRT through the seventh transistor T7, the residual charge may be reset.

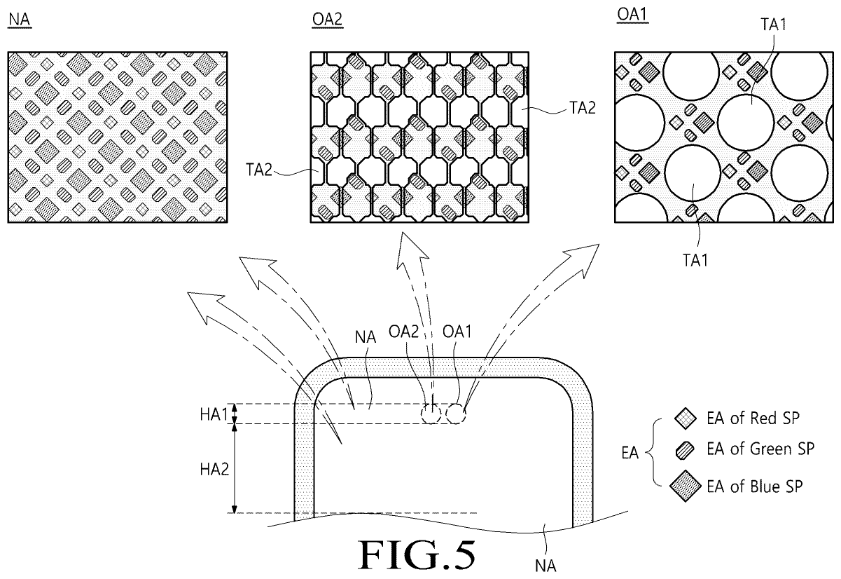

FIG. 5 is a diagram illustrating the arrangement of sub-pixels SP in the general area NA and the first and second optical areas OA1 and OA2 according to embodiments of the present disclosure.

Referring to FIG. 5, a plurality of sub-pixels SP may be arranged in each of the general area NA, the first optical area OA1, and the second optical area OA2 included in the display area DA.

For example, the plurality of sub-pixels SP may include red sub-pixels Red SP that emit red light, green sub-pixels Green SP that emit green light, and blue sub-pixels Blue SP that emit blue light.

Accordingly, each of the general area NA, the first optical area OA1, and the second optical area OA2 may include a plurality of emission areas EA corresponding to the red sub-pixels Red SP, a plurality of emission areas EA corresponding to the green sub-pixels Green SP, and a plurality of emission areas EA corresponding to the blue sub-pixels Blue SP.

Hereinafter, for convenience of description, the emission areas EA included in the first optical area OA1 and the second optical area OA2 may be referred to as first emission areas, and the emission areas EA included in the general area NA may be referred to as second emission areas.

Referring to FIG. 5, the general area NA may not include a transmissive area (i.e., a light-transmitting structure) but may include a plurality of emission areas EA.

However, the first optical area OA1 and the second optical area OA2 may include not only a plurality of emission areas EA but also a plurality of transmissive areas.

In other words, the first optical area OA1 may include a plurality of emission areas EA and a plurality of first transmissive areas TA1, and the second optical area OA2 may include a plurality of emission areas EA and a plurality of second transmissive areas TA2.

The plurality of emission areas EA and the plurality of first and second transmissive areas TA1 and TA2 may be distinguished based on whether they allow light transmission. Specifically, the plurality of emission areas EA may be areas where light transmission is blocked, while the plurality of first and second transmissive areas TA1 and TA2 may be areas where light transmission is possible.

Additionally, the plurality of emission areas EA and the plurality of first and second transmissive areas TA1 and TA2 may be distinguished based on the presence or absence of a specific metal layer. For example, a common electrode CE may be formed in the plurality of emission areas EA, while it may not be formed in the plurality of first and second transmissive areas TA1 and TA2. A light-shielding layer may be formed in the plurality of emission areas EA, whereas it may not be formed in the plurality of first and second transmissive areas TA1 and TA2.

Since the first optical area OA1 includes a plurality of first transmissive areas TA1 and the second optical area OA2 also includes a plurality of second transmissive areas TA2, the first optical area OA1 and the second optical area OA2 may be defined as areas where light (e.g., external light) can be transmitted.

The transmittance (degree of transparency) of the first optical area OA1 and the transmittance (degree of transparency) of the second optical area OA2 may be the same.

In this case, the first transmissive area TA1 of the first optical area OA1 and the second transmissive area TA2 of the second optical area OA2 may have the same shape or size. Alternatively, even if the first and second transmissive areas TA1 and TA2 of the first and second optical areas OA1 and OA2 have different shapes or sizes, the ratio of the first transmissive area TA1 within the first optical area OA1 and the ratio of the second transmissive area TA2 within the second optical area OA2 may be the same.

Conversely, the transmittance (degree of transparency) of the first optical area OA1 and the transmittance (degree of transparency) of the second optical area OA2 may be different.

In this case, the first transmissive area TA1 of the first optical area OA1 and the second transmissive area TA2 of the second optical area OA2 may have different shapes or sizes. Alternatively, even if the first and second transmissive areas TA1 and TA2 have the same shape or size, the ratio of the first transmissive area TA1 within the first optical area OA1 and the ratio of the second transmissive area TA2 within the second optical area OA2 may be different.

For example, if the first optoelectronic device 11 overlapping the first optical area OA1 is a camera and the second optoelectronic device 12 overlapping the second optical area OA2 is a sensor, the camera may require a greater amount of light than the sensor.

Accordingly, the transmittance (degree of transparency) of the first optical area OA1 may be higher than the transmittance (degree of transparency) of the second optical area OA2.

In this case, the first transmissive area TA1 of the first optical area OA1 may be larger than the second transmissive area TA2 of the second optical area OA2. Alternatively, even if the first and second transmissive areas TA1 and TA2 have the same size, the ratio of the first transmissive area TA1 within the first optical area OA1 may be greater than the ratio of the second transmissive area TA2 within the second optical area OA2.

As illustrated in FIG. 5, in embodiments of the present disclosure, the first and second transmissive areas TA1 and TA2 may also be referred to as transparent areas, and the transmittance may also be referred to as transparency.

Additionally, as illustrated in FIG. 5, in embodiments of the present disclosure, it is assumed that the first optical area OA1 and the second optical area OA2 are positioned at the top (in other words, at an upper portion) of the display area DA of the display panel 110 and are arranged side by side.

Referring to FIG. 5, the horizontal display area where the first optical area OA1 and the second optical area OA2 are arranged may be defined as a first horizontal display area HA1, and the horizontal display area where the first optical area OA1 and the second optical area OA2 are not arranged may be defined as a second horizontal display area HA2.

Referring to FIG. 5, the first horizontal display area HA1 may include the general area NA, the first optical area OA1, and the second optical area OA2. The second horizontal display area HA2 may include only the general area NA.

Hereinafter, for convenience of description, at least one of the first optical area OA1 and the second optical area OA2 may be referred to as an optical area OA, and at least one of the plurality of first transmissive areas TA1 within the first optical area OA1 and the plurality of second transmissive areas TA2 within the second optical area OA2 may be referred to as a transmissive area TA.

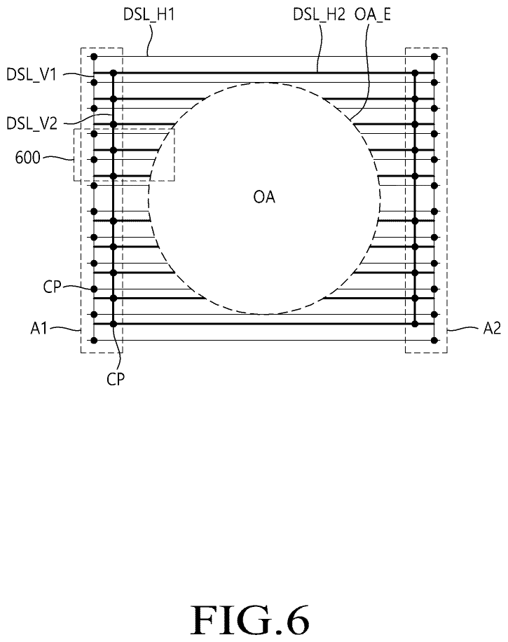

FIG. 6 is a diagram illustrating an example of the connection structure of signal lines in the display panel 110 according to embodiments of the present disclosure.

Referring to FIG. 6, the display panel 110 according to embodiments of the present disclosure may include, in the general area NA, a plurality of first signal lines (for example, first-1 and first-2 signal lines DSL_H1 and DSL_H2) extending in a first direction and at least one second signal line (for example, second-1 and second-2 signal lines DSL_V1 and DSL_V2) extending in a second direction crossing the first direction.

According to the example of FIG. 6, the first direction may be a horizontal (i.e., row) direction, and the second direction may be a vertical (i.e., column) direction. However, embodiments of the present disclosure are not limited thereto.

Each of the first signal lines (for example, first-1 and first-2 signal lines DSL_H1 and DSL_H2) may be electrically connected to a voltage line.

Here, the voltage line electrically connected to the plurality of first signal lines (for example, first-1 and first-2 signal lines DSL_H1 and DSL_H2) may be a DC signal line, which may include at least one of an initialization voltage line, a reset voltage line, and a bias voltage line.

The second signal line (for example, second-1 and second-2 signal lines DSL_V1 and DSL_V2) may electrically connect each of at least two first signal lines among the plurality of first signal lines (for example, first-1 and first-2 signal lines DSL_H1 and DSL_H2) that are electrically connected to the same voltage line, in a region adjacent to the optical area OA.

Each of the first signal lines (for example, first-1 and first-2 signal lines DSL_H1 and DSL_H2) and the second signal lines (for example, second-1 and second-2 signal lines DSL_V1 and DSL_V2) may be a data dummy line.

According to the example of FIG. 6, at least one of the plurality of first signal lines (for example, first-1 and first-2 signal lines DSL_H1 and DSL_H2) extending toward the optical area OA may be disconnected at an edge portion OA_E of the optical area OA.

In FIG. 6, the edge portion OA_E of the optical area OA is exemplified as a boundary line (a dotted line defining the optical area OA in FIG. 6) between the optical area OA and the general area NA. However, embodiments of the present disclosure are not limited thereto, and the edge portion OA_E of the optical area OA may include a region partially overlapping the optical area OA and a region partially overlapping the general area NA, based on the boundary line.

That is, the display device 100 according to embodiments of the present disclosure may electrically connect signal lines (for example, DC signal lines) in a region adjacent to the optical area OA by utilizing horizontal data dummy lines and vertical data dummy lines. This configuration may improve transmittance in the optical area OA while ensuring luminance uniformity in the optical area OA with minimal cost.

According to the example of FIG. 6, the first signal lines (for example, first-1 and first-2 signal lines DSL_H1 and DSL_H2) may be electrically connected to corresponding second signal lines (for example, second-1 and second-2 signal lines DSL_V1 and DSL_V2) in at least one of a first connection area A1, spaced apart by a predetermined distance from a first side (e.g., left side) of the optical area OA, and a second connection area A2, spaced apart by a predetermined distance from a second side (e.g., right side) of the optical area OA.

According to the example of FIG. 6, the first signal lines (for example, first-1 and first-2 signal lines DSL_H1 and DSL_H2) may include a plurality of first-1 signal lines DSL_H1 and a plurality of first-2 signal lines DSL_H2.

Additionally, the second signal lines (for example, second-1 and second-2 signal lines DSL_V1 and DSL_V2) may include a second-1 signal line DSL_V1, which electrically connects each of the plurality of first-1 signal lines DSL_H1 in the first connection area A1 and/or the second connection area A2, and a second-2 signal line DSL_V2, which electrically connects each of the plurality of first-2 signal lines DSL_H2 in the first connection area A1 and/or the second connection area A2.

For example, the plurality of first-1 signal lines DSL_H1 may be lines respectively connected to any one of an initialization voltage line, a reset voltage line, and a bias voltage line, while the plurality of first-2 signal lines DSL_H2 may be lines respectively connected to one of the initialization voltage line, reset voltage line, and bias voltage line, excluding the one connected to the first-1 signal lines DSL_H1.

However, the display device 100 according to embodiments of the present disclosure is not limited thereto. It may further include a plurality of first-3 signal lines extending in the first direction and respectively connected to the remaining one of the initialization voltage line, reset voltage line, and bias voltage line that is not connected to the first-1 signal lines DSL_H1 or the first-2 signal lines DSL_H2. Additionally, it may include a second-3 signal line extending in the second direction and electrically connecting each of the plurality of first-3 signal lines in the first connection area A1 and/or the second connection area A2.

The plurality of first-1 signal lines DSL_H1 and the plurality of first-2 signal lines DSL_H2 may be alternately arranged in the second direction in at least a portion of the display panel 110. For example, the at least a portion of the display panel 110 may be a region that at least partially overlaps the optical area OA.

According to the example of FIG. 6, in a portion of the display panel 110, the plurality of first-1 signal lines DSL_H1 may be arranged in odd-numbered rows, and the plurality of first-2 signal lines DSL_H2 may be arranged in even-numbered rows. However, embodiments of the present disclosure are not limited thereto, and the plurality of first-1 signal lines DSL_H1 may be arranged in even-numbered rows, while the plurality of first-2 signal lines DSL_H2 may be arranged in odd-numbered rows.

Each of different voltage lines may be directly connected to the corresponding first signal lines (for example, first-1 and first-2 signal lines DSL_H1 and DSL_H2).

In other words, each of the different voltage lines may be designed so that they do not overlap, thereby preventing short circuits between voltage lines. This allows them to be connected to each of the corresponding first signal lines (for example, first-1 and first-2 signal lines DSL_H1 and DSL_H2) without jumping connections.

Meanwhile, if at least one first voltage line among the different voltage lines overlaps at least one second voltage line in at least one overlapping region on the same plane (i.e., same layer), the at least one first voltage line may be jump-connected in the at least one overlapping region to be connected to each of the corresponding first signal lines (for example, first-1 and first-2 signal lines DSL_H1 and DSL_H2).

For example, at least one first voltage line may have a lower line resistance than at least one second voltage line.

More specifically, if the reset voltage line and the bias voltage line among the initialization voltage line, reset voltage line, and bias voltage line are arranged on the same layer and overlap each other, and if the line resistance of the reset voltage line is lower than that of the bias voltage line, the reset voltage line may be connected to a jump line arranged on a different plane (i.e., different layer) from the reset voltage line and the bias voltage line in the overlapping region. This may prevent short circuits between the reset voltage line and the bias voltage line in the overlapping region.

The first signal lines (for example, first-1 and first-2 signal lines DSL_H1 and DSL_H2) and the second signal lines (for example, second-1 and second-2 signal lines DSL_V1 and DSL_V2) may be formed of different materials on different planes. Each of the first signal lines (for example, first-1 and first-2 signal lines DSL_H1 and DSL_H2) may be formed of the same material on the same plane, and each of the second signal lines (for example, second-1 and second-2 signal lines DSL_V1 and DSL_V2) may be formed of the same material on the same plane.

The first signal lines (for example, first-1 and first-2 signal lines DSL_H1 and DSL_H2) and the second signal lines (for example, second-1 and second-2 signal lines DSL_V1 and DSL_V2) corresponding to the first signal lines may be electrically connected via a connection pattern CP in an overlapping region.

For example, the connection pattern CP may be formed of the same material as the second signal lines (for example, second-1 and second-2 signal lines DSL_V1 and DSL_V2). However, embodiments of the present disclosure are not limited thereto, and the connection pattern CP and the second signal lines (for example, second-1 and second-2 signal lines DSL_V1 and DSL_V2) may be formed of different materials.

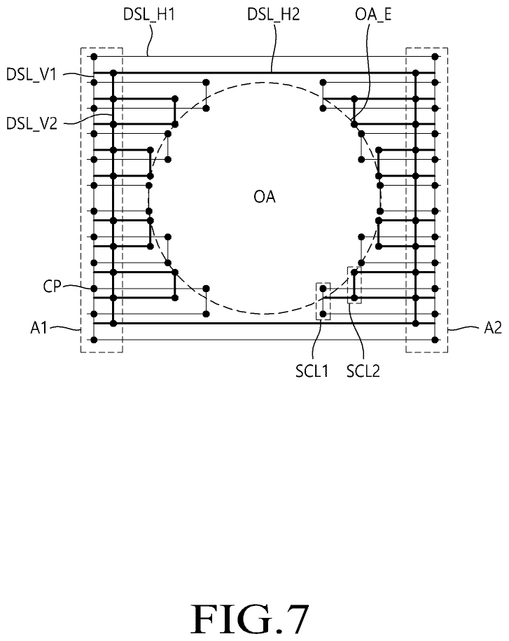

FIG. 7 is a diagram illustrating another example of the connection structure of signal lines in the display panel 110 according to embodiments of the present disclosure.

Referring to FIG. 7, the display panel 110 according to embodiments of the present disclosure may include a first auxiliary connection line SCL1, which electrically connects a pair of adjacent first-1 signal lines DSL_H1 among the plurality of first-1 signal lines DSL_H1 at the edge portion OA_E of the optical area OA, and a second auxiliary connection line SCL2, which electrically connects a pair of adjacent first-2 signal lines DSL_H2 among the plurality of first-2 signal lines DSL_H2 at the edge portion OA_E of the optical area OA.

According to the example of FIG. 7, the display device 100 may group the first-1 signal lines DSL_H1 corresponding to the position of the optical area OA in pairs in the second direction and connect the two first-1 signal lines grouped in the same group using the first auxiliary connection line SCL1 at the edge portion OA_E of the optical area OA.

Additionally, the display device 100 may group the first-2 signal lines DSL_H2 corresponding to the position of the optical area OA in pairs in the second direction and connect the two first-2 signal lines grouped in the same group using the second auxiliary connection line SCL2 at the edge portion OA_E of the optical area OA.

In other words, the display device 100 according to embodiments of the present disclosure may electrically connect each of the first signal lines (for example, first-1 and first-2 signal lines DSL_H1, DSL_H2) and the second signal lines (for example, second-1 and second-2 signal lines DSL_V1, DSL_V2) not only in the first connection area A1 and/or the second connection area A2 but also at the edge portion OA_E of the optical area OA. Through this way, the luminance uniformity in the optical area OA may be further improved by reducing luminance variation.

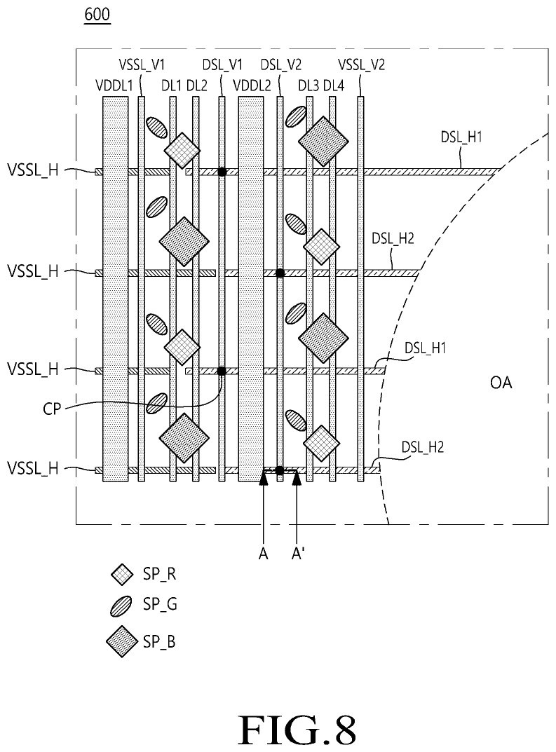

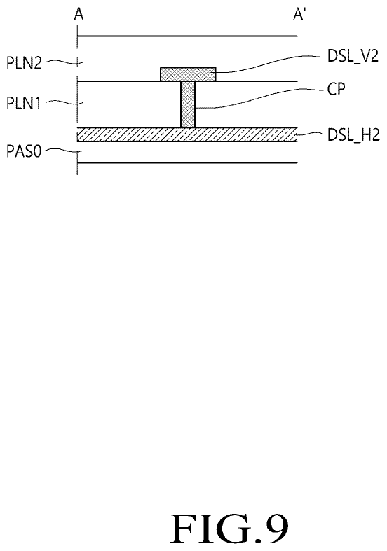

FIG. 8 and FIG. 9 are diagrams for further explaining the connection structure of signal lines in the display panel 110 according to embodiments of the present disclosure.

Specifically, FIG. 8 illustrates an enlarged plan view of the area corresponding to reference numeral 600 in FIG. 6, and FIG. 9 illustrates a cross-sectional view of the area corresponding to the A-A′ line in FIG. 8.

Referring to FIG. 8, the display panel 110 according to embodiments of the present disclosure may include a plurality of first ground voltage lines VSSL_H and a plurality of first signal lines (for example, first-1 and first-2 signal lines DSL_H1 and DSL_H2) extending in the first direction.

For example, each of the plurality of first ground voltage lines VSSL_H and the plurality of first signal lines (or example, first-1 and first-2 signal lines DSL_H1, DSL_H2) may be a data dummy line; however, embodiments of the present disclosure are not limited thereto.

Each of the plurality of first ground voltage lines VSSL_H may be connected to a main ground voltage line arranged in the non-display area NDA of the display panel 110 and may receive a ground voltage ELVSS. Each of the plurality of first signal lines (for example, first-1 and first-2 signal lines DSL_H1, DSL_H2) may be connected to any one of an initialization voltage line, a reset voltage line, and a bias voltage line arranged in the non-display area NDA of the display panel 110 and may receive a corresponding voltage among an initialization voltage Vini, a reset voltage VAR, and a bias voltage VOBS.

The display panel 110 according to embodiments of the present disclosure may include a plurality of driving voltage lines (for example, first and second driving voltage lines VDDL1, VDDL2), a plurality of data lines (for example, first to fourth data lines DL1, DL2, DL3, DL4), a plurality of second signal lines (for example, second-1 and second-2 signal lines DSL_V1, DSL_V2), and a plurality of second ground voltage lines (for example, second-1 and second-2 ground voltage lines VSSL_V1, VSSL_V2) extending in the second direction.

For example, each of the plurality of second ground voltage lines (for example, second-1 and second-2 ground voltage lines VSSL_V1, VSSL_V2) and the plurality of second signal lines (second-1 and second-2 signal lines DSL_V1, DSL_V2) may be a data dummy line; however, embodiments of the present disclosure are not limited thereto.

The plurality of driving voltage lines (for example, first and second driving voltage lines VDDL1, VDDL2) may be lines receiving a driving voltage ELVDD. Considering power loss and stability, they may be formed with a relatively larger line width than other lines (for example, first-1 and first-2 signal lines DSL_H1, DSL_H2, second-1 and second-2 signal lines DSL_V1, DSL_V2, first to fourth data lines DL1, DL2, DL3, and DL4).

The plurality of second ground voltage lines (for example, second-1 and second-2 ground voltage lines VSSL_V1, VSSL_V2) may be connected to a main ground voltage line arranged in the non-display area NDA of the display panel 110 and may receive the ground voltage ELVSS.

The plurality of data lines (for example, first to fourth data lines DL1, DL2, DL3, and DL4) may supply a data voltage VDATA to corresponding sub-pixels SP among the plurality of sub-pixels.

According to the example of FIG. 8, among the plurality of data lines (for example, first to fourth data lines DL1, DL2, DL3, and DL4), the first and third data lines DL1 and DL3 may be lines supplying a data voltage VDATA to adjacent green sub-pixels SP_G. The second and fourth data lines DL2 and DL4 may be lines supplying a data voltage VDATA to adjacent red sub-pixels SP_R and blue sub-pixels SP_B. However, embodiments of the present disclosure are not limited thereto.

According to the example of FIG. 8, the green sub-pixels SP_G, red sub-pixels SP_R, and blue sub-pixels SP_B may represent emission areas. That is, in FIG. 8, the green sub-pixels SP_G, red sub-pixels SP_R, and blue sub-pixels SP_B may represent light-emitting devices ED. Hereinafter, for convenience of explanation, the green sub-pixels SP_G, red sub-pixels SP_R, and blue sub-pixels SP_B are referred to as light-emitting devices ED or emission areas formed by the light-emitting devices ED.

Referring to FIG. 8, two green sub-pixels SP_G and one red sub-pixel SP_R and one blue sub-pixel SP_B arranged in the first direction or the second direction may constitute one unit pixel. In other words, the display panel 110 may include a plurality of unit pixels, and each of the plurality of unit pixels may include two green sub-pixels SP_G, one red sub-pixel SP_R, and one blue sub-pixel SP_B.

Referring to FIG. 8, the green sub-pixels SP_G may be arranged in the first direction (i.e., horizontal direction) and the second direction (i.e., vertical direction). The red sub-pixels SP_R and blue sub-pixels SP_B may be alternately arranged one by one in the first direction and the second direction.

The shapes and sizes of at least two of the green sub-pixels SP_G, red sub-pixels SP_R, and blue sub-pixels SP_B may be the same or different.

According to the example of FIG. 8, considering the lifetime and luminous efficiency of the emission material for each color, the blue sub-pixels SP_B may be formed with a larger area than the green sub-pixels SP_G and red sub-pixels SP_R. However, embodiments of the present disclosure are not limited thereto.

Each of the plurality of first-1 signal lines DSL_H1 among the plurality of first signal lines (for example, first-1 and first-2 signal lines DSL_H1, DSL_H2) may be connected to the second-1 signal line DSL_V1 through a connection pattern CP in a region overlapping with the second-1 signal line DSL_V1.

Each of the plurality of first-2 signal lines DSL_H2 among the plurality of first signal lines (for example, first-1 and first-2 signal lines DSL_H1, DSL_H2) may be connected to the second-2 signal line DSL_V2 through a connection pattern CP in a region overlapping with the second-2 signal line DSL_V2.

Each of the plurality of first ground voltage lines VSSL_H may be electrically connected to the second-1 ground voltage line VSSL_V1 in a overlapping region overlapping with the second-1 ground voltage line VSSL_V1 among the plurality of second ground voltage lines (for example, second-1 and second-2 ground voltage lines VSSL_V1 and VSSL_V2), or it may not be connected depending on the embodiment.

Referring to FIG. 9, the first signal lines (for example, first-1 and first-2 signal lines DSL_H1 and DSL_H2) and the second signal lines (for example, second-1 and second-2 signal lines DSL_V1 and DSL_V2) may be arranged on different planes. Each of the first signal lines (for example, first-1 and first-2 signal lines DSL_H1 and DSL_H2) may be electrically connected to the corresponding second signal line (for example, the second-1 signal line DSL_V1 or the second-2 signal line DSL_V2) through a connection pattern CP in an overlapping region.

According to the example of FIG. 9, the first-2 signal line DSL_H2 may be disposed on a passivation layer PAS0, and the second-2 signal line DSL_V2 may be disposed on a first planarization layer PLN1 among a plurality of planarization layers (for example, the first planarization layer PLN1 and a second planarization layer PLN2) disposed on the passivation layer PAS0.

In the overlapping region of the first-2 signal line DSL_H2 and the second-2 signal line DSL_V2, a contact hole may be formed in the first planarization layer PLN1, and the first-2 signal line DSL_H2 and the second-2 signal line DSL_V2 may be electrically connected through a connection pattern CP disposed in the contact hole.

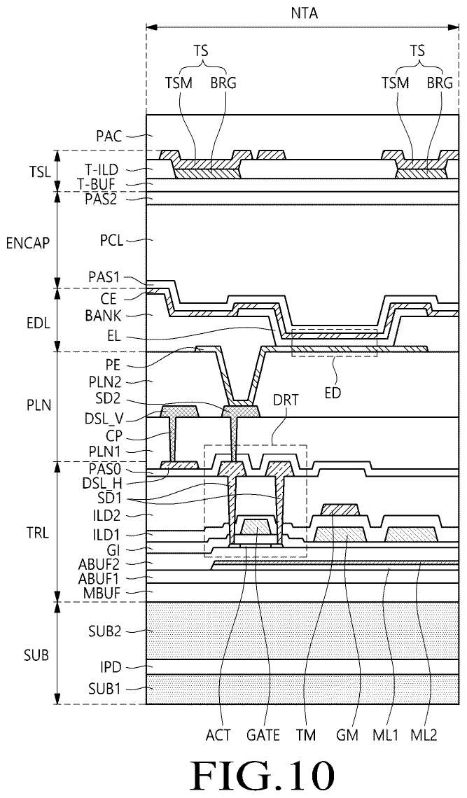

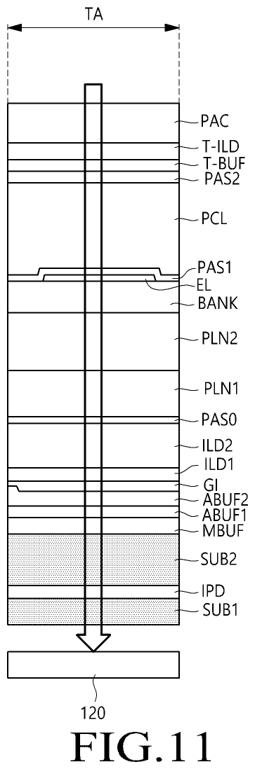

FIG. 10 and FIG. 11 are diagrams illustrating implementation examples of the display device 100 according to embodiments of the present disclosure.

Specifically, FIG. 10 illustrates a cross-sectional view of a non-transmissive area NTA in the general area NA of the display device 100 according to embodiments of the present disclosure. FIG. 11 illustrates a cross-sectional view of a transmissive area TA in the optical area OA of the display device 100 according to embodiments of the present disclosure.

Referring to FIG. 10 and FIG. 11, the display device 100 according to embodiments of the present disclosure may include a non-transmissive area NTA in the general area NA, a non-transmissive area NTA in the optical area OA, and a transmissive area TA in the optical area OA.

The non-transmissive area NTA of the optical area OA may include a first emission area, and the non-transmissive area NTA of the general area NA may include a second emission area. FIG. 10 illustrates an example of the non-transmissive area NTA in the general area NA.

For convenience of explanation, FIG. 11 illustrates an example in which the transmissive area TA of the optical area OA overlaps with the first optoelectronic device 11. However, the transmissive area TA of the optical area OA may also overlap with the second optoelectronic device 12.

Additionally, in FIG. 10 and FIG. 11, the first optoelectronic device 11 is illustrated as overlapping the transmissive area TA. However, the first optoelectronic device 11 may also overlap at least a portion of the non-transmissive area NTA included in the optical area OA.

The non-transmissive area NTA in the general area NA, the non-transmissive area NTA in the optical area OA, and the transmissive area TA in the optical area OA may include a substrate SUB, a transistor layer TRL, a planarization layer PLN, a light-emitting device layer EDL, an encapsulation layer ENCAP, a touch sensor layer TSL, and a protective layer PAC.

First, referring to FIG. 10, a stacked structure of the non-transmissive area NTA in the general area NA and the optical area OA will be described.

The substrate SUB may include a first substrate SUB1, an intermediate insulating film IPD, and a second substrate SUB2. The intermediate insulating film IPD may be positioned between the first substrate SUB1 and the second substrate SUB2. By configuring the substrate SUB with the first substrate SUB1, the intermediate insulating film IPD, and the second substrate SUB2, moisture infiltration may be prevented. For example, the first substrate SUB1 and the second substrate SUB2 may be polyimide (PI) substrates.

The intermediate insulating film IPD may include an inorganic material. For example, the intermediate insulating film IPD may include silicon nitride (SiNx) or silicon oxide (SiOx).

The transistor layer TRL may include various patterns (ACT, SD1, GATE) for forming transistors such as the driving transistor DRT, various insulating films (MBUF, ABUF1, ABUF2, GI, ILD1, ILD2, PAS0), and various metal patterns (TM, GM, ML1, ML2).

Depending on the embodiment, at least one additional insulating film may be disposed between a first interlayer insulating film ILD1 and a second interlayer insulating film ILD2 and/or between the second interlayer insulating film ILD2 and the passivation layer PAS0.

The stacked structure of the transistor layer TRL will now be described in more detail.

A multi-buffer layer MBUF may be disposed on the second substrate SUB2, and a first active buffer layer ABUF1 may be disposed on the multi-buffer layer MBUF.

A first metal layer ML1 and a second metal layer ML2 may be disposed on the first active buffer layer ABUF1. The first metal layer ML1 and the second metal layer ML2 may serve as a light shield.

The second active buffer layer ABUF2 may be disposed on the first metal layer ML1 and the second metal layer ML2. An active layer ACT of the driving transistor DRT may be disposed on the second active buffer layer ABUF2.

A gate insulating layer GI may be disposed on the second active buffer layer ABUF2 while covering the active layer ACT.

A gate electrode GATE of a driving transistor DRT may be disposed on the gate insulating layer GI. In this case, at a position different from where the driving transistor DRT is formed, a gate material layer GM may be disposed on the gate insulating layer GI together with the gate electrode GATE of the driving transistor DRT.

A first interlayer insulating layer ILD1 may be disposed on the gate insulating layer GI while covering the gate electrode GATE and the gate material layer GM. A metal pattern TM may be disposed on the first interlayer insulating layer ILD1. A second interlayer insulating layer ILD2 may be disposed on the first interlayer insulating layer ILD1 while covering the metal pattern TM.

Two first source-drain electrode patterns SD1 may be disposed on the second interlayer insulating layer ILD2. Among the two first source-drain electrode patterns SD1, one may be a source node (or drain node) of the driving transistor DRT, and the other may be a drain node (or source node) of the driving transistor DRT.

The two first source-drain electrode patterns SD1 may be connected to one side and the other side of the active layer ACT through contact holes in the second interlayer insulating layer ILD2, the first interlayer insulating layer ILD1, and the gate insulating layer GI. A portion of the active layer ACT overlapping with the gate electrode GATE may be a channel region. Among the two first source-drain electrode patterns SD1, one may be connected to one side of the channel region in the active layer ACT, and the other may be connected to the other side of the channel region in the active layer ACT.

A passivation layer PAS0 may be disposed on the second interlayer insulating layer ILD2 while covering the two first source-drain electrode patterns SD1.

In the non-transmissive area NTA of the general area NA, a first signal line DSL_H may be disposed on the passivation layer PAS0, where the first signal line DSL_H may include at least one of a first-1 signal line DSL_H1 and a first-2 signal line DSL_H2.

The first signal line DSL_H may be formed of the same material as the first source-drain electrode pattern SD1; however, embodiments of the present disclosure are not limited thereto.

According to an embodiment, the first signal line DSL_H may be disposed on the same plane (i.e., the second interlayer insulating layer ILD2) as the first source-drain electrode pattern SD1.

A planarization layer PLN may be disposed on the transistor layer TRL. The planarization layer PLN may include a first planarization layer PLN1 and a second planarization layer PLN2.

The first planarization layer PLN1 may be disposed on the passivation layer PAS0. A second source-drain electrode pattern SD2 may be disposed on the first planarization layer PLN1. The second source-drain electrode pattern SD2 may be connected to one of the two first source-drain electrode patterns SD1 (corresponding to the N2 node in FIG. 4) through a contact hole in the first planarization layer PLN1.

In the non-transmissive area NTA of the general area NA, a second signal line DSL_V may be disposed on the first planarization layer PLN1, where the second signal line DSL_V may include at least one of a first-2 signal line DSL_V1 and a second-2 signal line DSL_V2.

In the non-transmissive area NTA of the general area NA, a contact hole may be formed in a region of the first planarization layer PLN1 where the first signal line DSL_H and the second signal line DSL_V overlap perpendicularly (or vertically). A connection pattern CP may be disposed in the contact hole of the first planarization layer PLN1 to electrically connect the first signal line DSL_H and the second signal line DSL_V.

For example, the connection pattern CP may be disposed in at least one of a first connection area A1 and a second connection area A2 adjacent to the optical area OA (for example, see FIG. 6 and FIG. 7).

The second planarization layer PLN2 may be disposed on the first planarization layer PLN1 while covering the second source-drain electrode pattern SD2 and the second signal line DSL_V in the non-transmissive area NTA of the general area NA. The second planarization layer PLN2 may be disposed on the the first planarization layer PLN1 while covering the second source-drain electrode pattern SD2 in the non-transmissive area NTA of the optical area NA. A light-emitting device layer EDL may be positioned (or disposed) on the second planarization layer PLN2.

The light-emitting device layer EDL may include a light-emitting device ED formed by a pixel electrode PE, a light-emitting layer EL, and a common electrode CE. The light-emitting layer EL may include an organic film.

The pixel electrode PE may be disposed on the second planarization layer PLN2, and the pixel electrode PE may be electrically connected to the second source-drain electrode pattern SD2 through a contact hole in the second planarization layer PLN2.

A bank BANK may be disposed on the second planarization layer PLN2 while covering the pixel electrode PE. The bank BANK may have an opening corresponding to the light-emitting area of the subpixel SP. A portion of the pixel electrode PE may be exposed through the opened portion (or the opening) of the bank BANK. The light-emitting layer EL may be disposed in the opened portion of the bank BANK and around it. Accordingly, the light-emitting layer EL may be disposed on the pixel electrode PE exposed through the opened portion of the bank BANK.

A common electrode CE may be disposed on the light-emitting layer EL. For example, the common electrode CE may be a cathode electrode.

An encapsulation layer ENCAP may be disposed on the above-described light-emitting device layer EDL.

The encapsulation layer ENCAP may have a single-layer or multi-layer structure. For example, the encapsulation layer ENCAP may include a lower encapsulation layer PAS1, an intermediate encapsulation layer PCL, and an upper encapsulation layer PAS2.

However, the display device 100 according to embodiments of the present disclosure is not limited thereto and may include only the intermediate encapsulation layer PCL.

The lower encapsulation layer PAS1 and the upper encapsulation layer PAS2 are inorganic films, and the intermediate encapsulation layer PCL may be an organic or inorganic film. The intermediate encapsulation layer PCL may serve as a planarization layer.

The lower encapsulation layer PAS1 is disposed on the common electrode CE and may be positioned closest to the light-emitting device ED. The lower encapsulation layer PAS1 may be formed of an inorganic insulating material capable of low-temperature deposition. For example, the lower encapsulation layer PAS1 may be silicon nitride (SiNx), silicon oxide (SiOx), silicon oxynitride (SiON), or aluminum oxide (Al₂O₃). Since the lower encapsulation layer PAS1 is deposited in a low-temperature environment, it can prevent damage to the light-emitting layer EL, which contains organic material susceptible to high temperatures during a deposition process.

The intermediate encapsulation layer PCL serves as a buffer that alleviates stress between layers caused by the bending of the display device 100 and may enhance planarization performance. For example, the intermediate encapsulation layer PCL may be formed of an organic insulating material such as acrylic resin, epoxy resin, polyimide, polyethylene, or silicon oxycarbon (SiOC). The intermediate encapsulation layer PCL may be formed by an inkjet method.

The display device 100 (in particular, the display panel 110) may include at least one dam at or near the end of a slope of the encapsulation layer ENCAP to prevent the collapse of the encapsulation layer ENCAP. The at least one dam may be located at or near the boundary between the display area DA and the non-display area NDA.

The intermediate encapsulation layer PCL, which includes organic material, may be positioned only on the inner side of a primary dam. In other words, the intermediate encapsulation layer PCL may not be present at the top of all the dams. Alternatively, the intermediate encapsulation layer PCL may be positioned at the top of at least the primary dam of primary and secondary dams. That is, the intermediate encapsulation layer PCL may extend only to the top of the primary dam. Or, the intermediate encapsulation layer PCL may extend beyond the top of the primary dam to the top of the secondary dam.

The upper encapsulation layer PAS2 may be formed on the substrate SUB, where the intermediate encapsulation layer PCL is formed, and cover the upper and side surfaces of both the intermediate encapsulation layer PCL and the lower encapsulation layer PAS1. The upper encapsulation layer PAS2 may minimize or block external moisture and oxygen from penetrating the lower encapsulation layer PAS1 and the intermediate encapsulation layer PCL. For example, the upper encapsulation layer PAS2 may be formed of an inorganic insulating material such as silicon nitride (SiNx), silicon oxide (SiOx), silicon oxynitride (SiON), or aluminum oxide (Al₂O₃).

A touch sensor layer TSL may be disposed on the encapsulation layer ENCAP.

A touch buffer layer T-BUF may be disposed on the encapsulation layer ENCAP, and a touch sensor TS may be disposed on the touch buffer layer T-BUF. The touch sensor TS may include touch sensor metals TSM and bridge metal BRG located on different layers. A touch interlayer insulating film T-ILD may be disposed between the touch sensor metals TSM and the bridge metal BRG.

For example, the touch sensor metals TSM may include a first touch sensor metal, a second touch sensor metal, and a third touch sensor metal, which are arranged adjacent to each other. The first touch sensor metal and the second touch sensor metal need to be electrically connected. However, if the third touch sensor metal is present between them, the first touch sensor metal and the second touch sensor metal may be electrically connected via the bridge metal BRG located on a different layer. The bridge metal BRG may be insulated from the third touch sensor metal by the touch interlayer insulating film T-ILD.

During the formation of the touch sensor layer TSL, chemical solutions used in the process of formation (such as developer or etchant) or external moisture may be generated. By placing the touch buffer layer T-BUF and then forming the touch sensor layer TSL on top of it, the penetration of these chemical solutions or moisture into the light-emitting layer EL, which contains organic material, can be prevented during the manufacturing process of the touch sensor layer TSL. As a result, the touch buffer layer T-BUF may protect the light-emitting layer EL, which is vulnerable to chemical solutions or moisture, from damage.

To prevent damage to the light-emitting layer EL, which includes organic material vulnerable to high temperatures, the touch buffer layer T-BUF is formed of an organic insulating material that can be deposited at a low temperature (e.g., 100° C. or lower) and has a low dielectric constant of about 1 to 3. For example, the touch buffer layer T-BUF may be formed of acrylic-based, epoxy-based, or siloxane-based material. Generally, when the display device 100 bends, the encapsulation layer ENCAP may be damaged, and the touch sensor metals of the touch sensor TS located on the touch buffer layer T-BUF may crack. However, according to the embodiments of the present disclosure, even if the display device 100 bends, the touch buffer layer T-BUF, which has planarization properties due to its organic insulating material, may prevent damage to the encapsulation layer ENCAP and/or cracking of the touch sensor metal TSM and the bridge metal BRG that form the touch sensor TS.

A protective layer PAC may be disposed over the touch sensor TS. The protective layer PAC may be an organic insulating film.

The following content describes a laminated structure of the transmissive area TA within the optical area OA with reference to FIG. 11.

Referring to FIG. 11, the substrate SUB and insulating layers (for example, MBUF, ABUF1, ABUF2, GI, ILD1, ILD2, PAS0, PLN1, PLN2, BANK, and ENCAP, PAS1, PCL1, PCL2, PAS2, PAC), arranged in the non-transmissive area NTA, may be arranged similarly in the transmissive area TA within the optical area OA.

However, except for insulating materials in the non-transmissive area NTA, material layers with electrical properties (e.g., metal material layers, semiconductor layers, etc.) may not be disposed in the transmissive area TA.

For example, metal material layers (for example, ML1, ML2, GATE, GM, TM, SD1, and SD2), and the semiconductor layer ACT related to transistors may not be disposed in the transmissive area TA. Additionally, the pixel electrode PE and the common electrode CE included in the light-emitting device ED may not be disposed in the transmissive area TA. The light-emitting layer EL may or may not be disposed in the transmissive area TA. The touch sensor metals TSM and bridge metal BRG included in the touch sensor TS may not be disposed in the transmissive area TA.

The embodiments of the present disclosure described above are summarized as follows.

The display device according to embodiments of the present disclosure may include a display panel comprising an optical area and a general area. The optical area may comprise a plurality of transmissive areas and a plurality of first emission areas, and the general area may be disposed outside the optical area and may comprise a plurality of second emission areas. The display device may further include an optoelectronic device disposed below the display panel and overlapping the optical area.

The general area may comprise a plurality of signal lines connected in a mesh structure in a region adjacent to the optical area.

The plurality of signal lines may include a plurality of first signal lines extending in the first direction and at least one second signal line extending in the second direction, which intersects the first direction, electrically connecting each of at least two first signal lines among the plurality of first signal lines that are electrically connected to the same voltage line, in a region adjacent to the optical area.

Each of the plurality of first signal lines and at least one second signal line may be a data dummy line.

At least two of the first signal lines may be electrically connected to at least one second signal line in at least one connection area, which is spaced a predetermined distance from the first side of the optical area, or in a second connection area, which is spaced a predetermined distance from the second side of the optical area.

The voltage lines may include at least one of an initialization voltage line, a reset voltage line, and a bias voltage line.

At least one of the plurality of first signal lines extending in the direction of the optical area may be disconnected at the edge portion of the optical area.

At least two of the first signal lines may include a plurality of first-one signal lines electrically connected to a first voltage line and a plurality of first-two signal lines electrically connected to a second voltage line.

At least one second signal line may include a second-1 signal line electrically connecting each of the plurality of first-1 signal lines and a second-2 signal line electrically connecting each of the plurality of first-2 signal lines.

The plurality of first-1 signal lines and the plurality of first-2 signal lines may be alternately arranged in the second direction in at least a portion of the display panel.

The at least a portion of the display panel may be a region that at least partially overlaps the optical area.

Each of the plurality of first-1 signal lines may be connected to the second-1 signal line through a connection pattern in a region overlapping with the second-1 signal line, and each of the plurality of first-2 signal lines may be connected to the second-2 signal line through a connection pattern in a region overlapping with the second-2 signal line.

The connection pattern may be disposed in at least one of a first connection area and a second connection area adjacent to the optical area.

The display device may further include a first auxiliary connection line electrically connecting an adjacent pair of the plurality of first-1 signal lines at the edge portion of the optical area and a second auxiliary connection line electrically connecting an adjacent pair of the plurality of first-2 signal lines at the edge portion of the optical area.

If at least one first voltage line among different voltage lines overlaps at least one second voltage line among different voltage lines in at least one overlapping region on the same plane, at least one first voltage line may be jump-connected in the at least one overlapping region.

At least one first voltage line may have a lower line resistance than at least one second voltage line.

The plurality of first signal lines and at least one second signal line may be formed of different materials on different planes.

The display device may further include a connection pattern electrically connecting each of the plurality of first signal lines to at least one second signal line.

Each of the plurality of first signal lines may be formed of the same material on the same plane.

The display panel of the display device may further include a substrate, a transistor layer that is disposed on the substrate and includes at least one transistor and a passivation layer disposed on the at least one transistor, and a plurality of planarization layers disposed on the transistor layer.

The plurality of first signal lines may be disposed on the passivation layer, and at least one second signal line may be disposed on any one of the plurality of planarization layers.

The display device may further include a connection pattern disposed in each contact hole formed in a region where each of the plurality of first signal lines overlaps at least one second signal line, electrically connecting each of the plurality of first signal lines to at least one second signal line.

The connection pattern may be formed of the same material as at least one second signal line.

There may be no material layers with electrical properties in the plurality of transmissive areas.

The display device according to embodiments of the present disclosure may comprise a display panel including a general area and an optical area, where the optical area overlaps an optoelectronic device disposed below the display panel. The display panel may comprise: a substrate; a transistor layer disposed on the substrate and including at least one transistor and a passivation layer disposed on the at least one transistor; a first signal line disposed on the passivation layer in the general area and electrically connected to a voltage line; a plurality of planarization layers disposed on the transistor layer and the first signal line; a second signal line disposed on any one of the plurality of planarization layers in the general area and electrically connected to the first signal line in a region adjacent to the optical area; and a light-emitting device layer disposed on the plurality of planarization layers and including a plurality of light-emitting devices corresponding to each of the optical area and the general area.

The plurality of planarization layers may include a first planarization layer disposed on the passivation layer and the first signal lines, and a second planarization layer disposed on the first planarization layer, and the second signal line may be disposed on the second planarization layer.

The display device may further include a connection pattern disposed in a contact hole formed in the first planarization layer, electrically connecting the first signal line and the second signal line.

The substrate may include a first substrate, an intermediate insulating layer disposed on the first substrate, and a second substrate disposed on the intermediate insulating layer.

The optical area may include a transmissive area, and the transmissive area may overlap the light-emitting layer in the light-emitting device in the transmissive area.

The above description has been presented to enable any person skilled in the art to make and use the technical idea of the present invention, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the present invention. The above description and the accompanying drawings provide an example of the technical idea of the present invention for illustrative purposes only. That is, the disclosed embodiments are intended to illustrate the scope of the technical idea of the present invention.

What is claimed is:

1. A display device, comprising:
a display panel including an optical area and a general area, wherein the optical area comprises a plurality of transmissive areas and a plurality of first emission areas, and wherein the general area is disposed outside the optical area and comprises a plurality of second emission areas; and
an optoelectronic device disposed below the display panel and overlapping the optical area,
wherein the general area comprises a plurality of signal lines connected in a mesh structure in a region adjacent to the optical area.

2. The display device of claim 1, wherein the plurality of signal lines comprises:
a plurality of first signal lines extending in a first direction, wherein each of the plurality of first signal lines is electrically connected to a voltage line; and
at least one second signal line extending in a second direction intersecting the first direction and electrically connecting each of at least two first signal lines among the plurality of first signal lines that are electrically connected to the same voltage line, in a region adjacent to the optical area.

3. The display device of claim 2, wherein each of the plurality of first signal lines and the at least one second signal line is a data dummy line.

4. The display device of claim 2, wherein the at least two first signal lines are electrically connected to the at least one second signal line in at least one of:
a first connection area spaced apart from a first side of the optical area by a predetermined distance; and
a second connection area spaced apart from a second side of the optical area by the predetermined distance.

5. The display device of claim 2, wherein the voltage line comprises at least one of an initialization voltage line, a reset voltage line, and a bias voltage line.

6. The display device of claim 2, wherein at least one of the plurality of first signal lines extending toward the optical area is disconnected at an edge portion of the optical area.

7. The display device of claim 2, wherein the at least two first signal lines comprise a plurality of first-1 signal lines electrically connected to a first voltage line and a plurality of first-2 signal lines electrically connected to a second voltage line.

8. The display device of claim 7, wherein the at least one second signal line comprises a second-1 signal line electrically connected to each of the plurality of first-1 signal lines, and a second-2 signal line electrically connected to each of the plurality of first-2 signal lines.

9. The display device of claim 7, wherein the plurality of first-1 signal lines and the plurality of first-2 signal lines are alternately arranged in the second direction in at least a portion of the display panel.

10. The display device of claim 9, wherein the at least a portion of the display panel is a region that at least partially overlaps the optical area.

11. The display device of claim 8, wherein each of the plurality of first-1 signal lines is connected to the second-1 signal line through a first connection pattern in a region overlapping with the second-1 signal line, and each of the plurality of first-2 signal lines is connected to the second-2 signal line through a second connection pattern in a region overlapping with the second-2 signal line.

12. The display device of claim 11, wherein each of the first connection pattern and the second connection pattern is disposed in at least one of a first connection area and a second connection area adjacent to the optical area.

13. The display device of claim 7, further comprising:
a first auxiliary connection line electrically connected to an adjacent pair of the plurality of first-1 signal lines at an edge portion of the optical area; and
a second auxiliary connection line electrically connected to an adjacent pair of the plurality of first-2 signal lines at the edge portion of the optical area.

14. The display device of claim 2, wherein when at least one first voltage line among different voltage lines overlaps at least one second voltage line among different voltage lines in at least one overlapping region on a same plane, the at least one first voltage line is jump-connected in the at least one overlapping region.

15. The display device of claim 14, wherein the at least one first voltage line has a lower line resistance than the at least one second voltage line.

16. The display device of claim 2, wherein:
the plurality of first signal lines and the at least one second signal line are formed of different materials on different planes; and
the display device further comprises a connection pattern electrically connecting each of the plurality of first signal lines to the at least one second signal line.

17. The display device of claim 2, wherein each of the plurality of first signal lines is formed of a same material on a same plane.

18. The display device of claim 2, wherein the display panel comprises:
a substrate;
a transistor layer disposed on the substrate and including at least one transistor and a passivation layer disposed on the at least one transistor; and
a plurality of planarization layers disposed on the transistor layer,
wherein the plurality of first signal lines is disposed on the passivation layer, and the at least one second signal line is disposed on any one of the plurality of planarization layers.

19. The display device of claim 18, further comprising a connection pattern disposed in each contact hole formed in an overlapping region of each of the plurality of first signal lines and the at least one second signal line, wherein the connection pattern electrically connects each of the plurality of first signal lines to the at least one second signal line.

20. The display device of claim 19, wherein the connection pattern is formed of a same material as the at least one second signal line.
